(19) United States
(12) Patent Application Publication
(10) Pub. No.: US 2004/0219709 A1
(43) Pub. Date: Nov. 4, 2004

(54) Method for fabricating complementary metal oxide semiconductor image sensor

(76) Inventor: Won-Ho Lee, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/746,161

(22) Filed: Dec. 24, 2003

(30) Foreign Application Priority Data
Apr. 29, 2003 (KR) 2003-26968

(51) Int. Cl. H01L 21/00

(52) U.S. Cl. 438/57

(57) ABSTRACT

The present invention relates to a method for fabricating a complementary metal oxide semiconductor image sensor. The method includes the steps of: forming a gate structure having a spacer and a gate on a substrate; and forming a buffer layer covering a surface of the substrate and the spacer and exposing a portion of a surface of the gate by using a selective etching process.

### FIELD OF THE INVENTION

The present invention relates to a method for fabricating a complementary metal oxide semiconductor (CMOS) image sensor; and, more particularly, to a method for fabricating a CMOS image sensor with a salicide layer.

### DESCRIPTION OF RELATED ARTS

Generally, a complementary metal oxide semiconductor (CMOS) image sensor is a semiconductor device that converts an optical image into an electric signal. The CMOS image sensor includes a photo-detection unit for detecting a light and a logic circuit for processing the detected light into an electric signal, which is, in turn, converted into a corresponding datum. The CMOS technology adopts a switching mode, wherein outputs are sequentially detected by using MOS transistors made with the same number as that of pixels.

The CMOS image sensor is classified into a pixel region and a peripheral region. Particularly, a pixel array is formed in the pixel region, while N-cannel metal oxide semiconductor (NMOS) and P-channel metal oxide semiconductor (PMOS) transistors are formed in the peripheral region. A unit pixel in the pixel array includes one photodiode PD which is a device for collecting light and four transistors such as a transfer transistor, a reset transistor, a drive transistor and a selection transistor. In more detail, the transfer transistor transfers the collected light at the photodiode to a floating diffusion node. The reset transistor sets the floating diffusion node with an intended electric potential value and then resets the floating diffusion node with an electric potential value by discharging the photo-generated electric charge. The drive transistor serves as a source follower buffer amplifier, and the selection transistor selectively outputs the electric potential value corresponding to the photo-generated electric charge.

In the CMOS image sensor, a salicide layer is formed in an upper part of an active region in which a polysilicon line pattern, e.g., a gate, and a junction region, e.g., a source/drain, are typically formed in order to improve operation speed of the CMOS image sensor. Especially, the salicide layer is formed by employing a self-aligned silicide process. More specifically, the salicide layer is formed in an upper portion of the gate to secure an input/output region with a high resistance and protect the photodiode in the pixel region. Therefore, a salicide barrier layer is formed prior to performing a salicide process in order to prevent the salicide layer from being formed in the upper part of the active region.

FIGS. 1A to 1C are cross-sectional views illustrating a method for fabricating a conventional CMOS image sensor with the above described salicide barrier layer.

Referring to FIG. 1A, a gate insulation layer 11 and a gate 12 are formed on a substrate 10, and a spacer 13 made of oxide is formed on sidewalls of the gate 12. Then, a salicide barrier layer 14 is deposited along a resulting profile containing the substrate 10. A bottom anti-reflective coating (BARC) layer 15 is formed on the salicide barrier layer 14. Herein, the salicide barrier layer 14 is an oxide-based layer. Preferably, high temperature low pressure dielectric (HLD) oxide is used to form the salicide barrier layer 14 with a thickness ranging from about 600 Å to about 700 Å.

Referring to FIG. 1B, the BARC layer 15 is subjected to an etch-back process with a target to expose the salicide barrier layer 14 disposed on an upper part of the gate 12.

Referring to FIG. 1C, the exposed salicide barrier layer 14 is subjected to an etch-back process with a target to expose an upper surface of the gate 12.

Although not illustrated, a photoresist pattern masking a portion of the active region in which the salicide layer is not formed and opening the rest portions is formed on the above resulting structure. Then, the exposed portions of the BARC layer 15 and the salicide barrier layer 14 are removed. Afterwards, the photoresist pattern is removed, and a salicide process is performed thereafter.

However, in the above conventional method, the spacer 13 is also exposed and damaged while the etch-back process is performed to the oxide-based salicide barrier layer 14. The damaged portions of the spacer 13 are denoted as the numeral reference 100. The damaged portions 100 result in profile deformation of the spacer 13, which subsequently induces a channeling phenomenon during an ion-implantation process performed with use of the spacer 13. Also, the deformed profile of the spacer 13 deteriorates electric characteristics of a transistor and increases a probability of bridge generations between the salicide layers. As a result, properties and reliability of the CMOS image sensor are degraded.

### SUMMARY OF THE INVENTION

It is, therefore, an object of the present invention to provide a method for fabricating a complementary metal oxide semiconductor (CMOS) image sensor with improved reliability and characteristics by effectively preventing a spacer from being exposed and damaged during an etch-back process performed to a salicide barrier layer.

In accordance with an aspect of the present invention, there is provided a method for fabricating a complementary metal oxide semiconductor (CMOS) image sensor, including the steps of: forming a gate structure having a spacer and a gate on a substrate; and forming a buffer layer covering a surface of the substrate and the spacer and exposing a portion of a surface of the gate by using a selective etching process.

### BRIEF DESCRIPTION OF THE DRAWING(S)

The above and other objects and features of the present invention will become apparent from the following description of the preferred embodiments given in conjunction with the accompanying drawings, in which:

FIGS. 1A to 1C are cross-sectional views illustrating a method for fabricating a conventional complementary metal oxide semiconductor (CMOS) image sensor; and

FIGS. 2A to 2E are cross-sectional views illustrating a method for fabricating a CMOS image sensor in accordance with a preferred embodiment of the present invention.

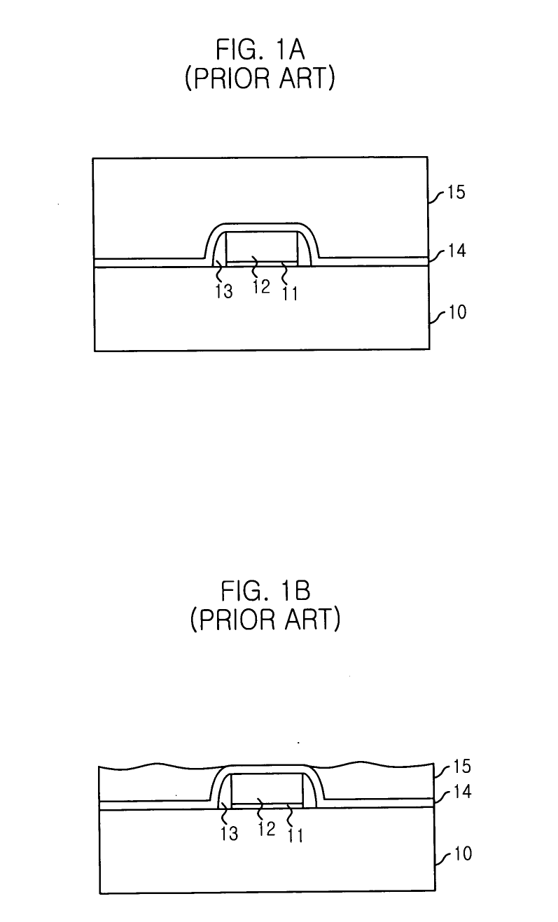

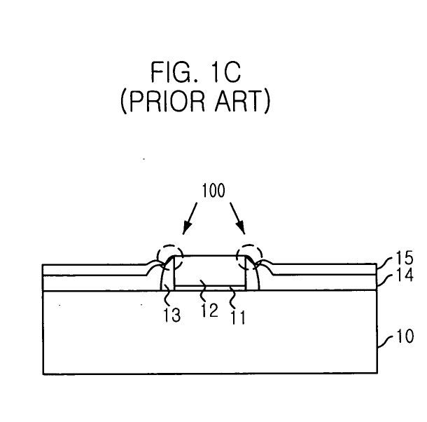

### DETAILED DESCRIPTION OF THE INVENTION

Hereinafter, a preferred embodiment of the present invention will be described in detail with reference to the accompanying drawings.

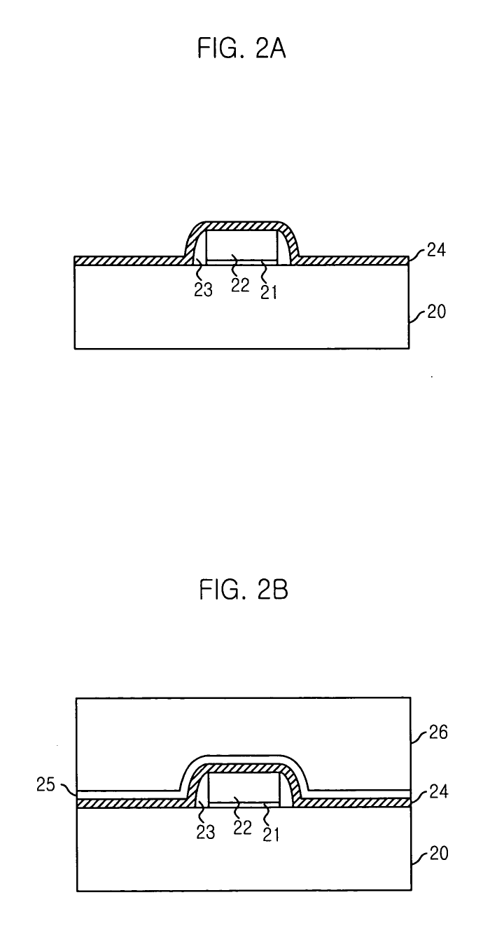

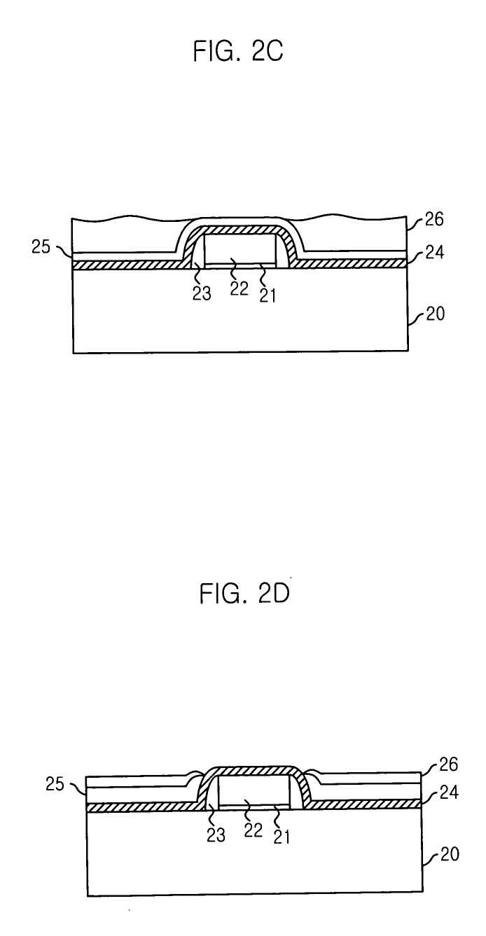

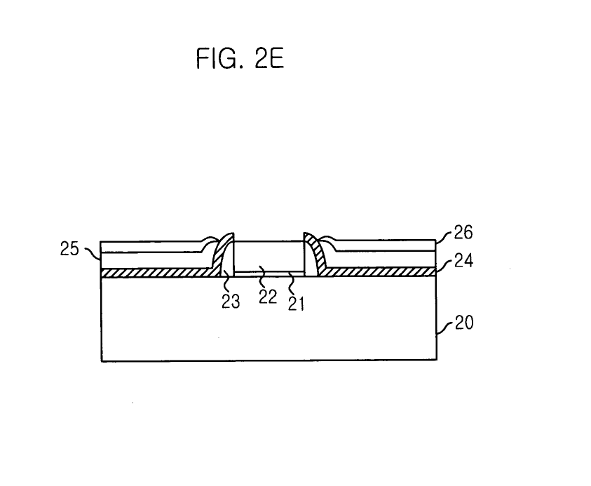

FIGS. 2A to 2E are cross-sectional views illustrating a method for fabricating a complementary metal oxide semiconductor (CMOS) image sensor in accordance with a preferred embodiment of the present invention.

Referring to FIG. 2A, a gate insulation layer 21 and a gate 22 are formed on a substrate 20, and a spacer 23 made of oxide is formed on sidewalls of the gate 22. That is, a gate structure including the gate insulation layer 21, the gate 22 and the spacer 23 is formed. Then, a buffer layer 24 is formed along the gate structure such that the buffer layer 24 covers the spacer 23 and the gate structure. At this time, the buffer layer 24 has a thickness ranging from about 500 Å to about 700 Å. Also, the buffer layer 24 serves as a protection layer for preventing the spacer 23 from being exposed and damaged during a subsequent etch-back process performed to a salicide barrier layer which will be subsequently formed. Preferably, the buffer layer 24 is made of nitride. If the buffer layer 24 is made of nitride, it is possible to secure the spacer 23 with a good etch selectivity when the buffer layer 24 is subjected to a wet etching process and to minimize losses of light reflected from a surface of the substrate 20.

Referring to FIG. 2B, the above mentioned salicide barrier layer 25 and a bottom anti-reflective coating (BARC) layer 26 are sequentially deposited on the buffer layer 24. Herein, the salicide barrier layer 25 is an oxide-based layer. Preferably, high temperature low pressure dielectric (HLD) oxide is used to form the salicide barrier layer 25 with a thickness ranging from about 600 Å to about 700 Å.

Referring to FIG. 2C, the BARC layer 26 is subjected to an etch-back process with a target to expose the salicide barrier layer 25 disposed on an upper surface of the gate 22.

Referring to FIG. 2D, the salicide barrier layer 25 is then subjected to an etch-back process with a target to expose the buffer layer 24 disposed on the upper surface of the gate 22. At this time, the buffer layer 24 prevents the spacer 23 from being exposed and damaged even if the etch-back process is performed to the salicide barrier layer 25.

Referring to FIG. 2E, the exposed buffer layer 24 is selectively removed by employing a wet etching process using phosphoric acid (H₃PO₄) to thereby the upper surface of the gate 22 is exposed.

Although not illustrated, a photoresist pattern masking a portion of the active region in which the salicide layer 25 is not formed and opening the rest portions is formed on the above resulting structure. Then, the exposed portions of the salicide barrier layer 25 and the BARC layer 26 are removed. Afterwards, the photoresist pattern is removed, and a salicide process proceeds thereafter.

On the basis of the preferred embodiment of the present invention, the buffer layer is formed on between the spacer and the salicide barrier layer to prevent the spacer from being exposed and damaged during the etch-back process applied to the salicide barrier layer. As a result, it is further possible to prevent profile deformation of the spacer. Also, because of this effect, an incidence of channeling phenomenon and bridge generations between the salicide layers can be suppressed. Furthermore, it is also possible to prevent electric characteristics of a transistor from being degraded.

Additionally, the use of nitride as the buffer layer minimizes losses of light reflected from a surface of the substrate to thereby realize the CMOS image sensor with high sensitivity. Eventually, it is possible to improve reliability and characteristics of the CMOS image sensor.

Although the preferred embodiment of the present invention exemplifies the use of nitride as the buffer layer, it is still possible to use oxygen contained nitride. Also, if the spacer formed on the sidewalls of the gate structure is made of nitride, the buffer layer is formed with oxide. Conversely, the salicide barrier layer is made of oxygen contained nitride or nitride. In such case, the removal of the buffer layer proceeds through a wet etching process using buffer oxide etchant (BOE).

Also, the preferred embodiment of the present invention shows that the buffer layer is selectively removed without using a mask but by performing the wet etching process. However, the buffer layer can be removed by performing a dry etching process with use of another type of a gate mask pattern formed by employing a reticle for use in a gate and a negative photoresist pattern.

While the present invention has been described with respect to certain preferred embodiments, it will be apparent to those skilled in the art that various changes and modifications may be made without departing from the scope of the invention as defined in the following claims.

What is claimed is:

1. A method for fabricating a complementary metal oxide semiconductor (CMOS) image sensor, comprising the steps of:
forming a gate structure having a spacer and a gate on a substrate; and
forming a buffer layer covering a surface of the substrate and the spacer and exposing a portion of a surface of the gate by using a selective etching process.

2. The method as recited in claim 1, further comprising the steps of:
sequentially forming a salicide barrier layer and a bottom anti-reflective coating (BARC) layer on the buffer layer;
performing an etch-back process to the BARC layer to expose the salicide barrier layer disposed on an upper surface of the gate structure;
performing an etch-back process to the salicide barrier layer to expose the buffer layer disposed on the upper surface of the gate structure; and
removing the exposed buffer layer to expose the upper surface of the gate.

3. The method as recited in claim 1, wherein the spacer is made of oxide and the buffer layer is made of nitride or oxynitride.

4. The method as recited in claim 3, wherein the salicide barrier layer is made of oxide.

5. The method as recited in claim 4, wherein the buffer layer is removed by performing a wet etching process using phosphoric acid (H₃PO₄).

6. The method as recited in claim 1, wherein the spacer is made of nitride and the buffer layer is made of oxide.

7. The method as recited in claim 4, wherein the salicide barrier layer is made of oxynitride and nitride.

8. The method as recited in claim 2, wherein the buffer layer is removed by performing a wet etching process using a buffer oxide etchant.

9. The method as recited in claim 3, wherein the buffer layer has a thickness ranging from about 500 Å to about 700 Å.

10. The method as recited in claim 3, wherein the buffer layer has a thickness ranging from about 500 Å to about 700 Å.

11. The method as recited in claim 2, wherein the buffer layer is removed by performing a dry etching process using a mask formed by using a reticle for use in the gate structure and a negative photoresist pattern.
